(19) United States
(12) Patent Application Publication
(10) Pub. No.: US 2007/0080350 A1
(43) Pub. Date: Apr. 12, 2007

(54) Panel for flexible display device and manufacturing method thereof

(75) Inventors: Hong-Kee Chin, Suwon-si (KR); Sang-Gab Kim, Seoul (KR); Tae-Hyung Hwang, Seoul (KR); Min-Seok Oh, Yongin-si (KR); Yu-Gwang Jeong, Yongin-si (KR); Seung-Ha Choi, Siheung-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/545,364

(22) Filed: Oct. 10, 2006

(30) Foreign Application Priority Data
Oct. 11, 2005 (KR) 10-2005-0095525

(51) Int. Cl. H01L 29/04; H01L 21/84

(52) U.S. Cl. 257/59; 257/72; 438/151; 257/E27.131

(57) ABSTRACT

A flexible display panel according to an embodiment of the present invention includes a flexible substrate, a gate line formed on the substrate and including a gate electrode, a gate insulating layer formed on the substrate, a semiconductor layer formed on the gate insulating layer and disposed substantially on the entire gate electrode, a source electrode and a drain electrode formed on the semiconductor layer, and a pixel electrode connected to the drain electrode. The patterning of the semiconductor layer to form a second semiconductor member may include coating a photoresist film on a first semiconductor member, exposing the photoresist film to light from a back of the substrate, wherein the gate electrode is used as a light blocking mask, developing the exposed photoresist film to form a photoresist pattern having the same planar size as the gate electrode, and etching the semiconductor layer using the photoresist pattern as an etching mask.

### CROSS-REFERENCE TO RELATED APPLICATION

This application claims priority to Korean Patent Application No. 10-2005-0095525 filed on Oct. 11, 2005, the entire contents of which are incorporated herein by reference.

### BACKGROUND OF THE INVENTION

(a) Technical Field

The present invention relates to a display panel for a flexible display device and a manufacturing method thereof.

(b) Discussion of the Related Art

A liquid crystal display and an organic light emitting diode (OLED) display are flat panel displays that are presently in use.

The liquid crystal display may include an upper panel in which a common electrode, and color filters are formed, a lower panel in which thin film transistors (TFTs) and pixel electrodes are formed, and a liquid crystal layer that is interposed between the two display panels. If a potential difference between a pixel electrode and the common electrode is generated, an electric field is generated in the liquid crystal layer and the orientation of liquid crystal molecules is determined based on the electric field. Transmittance of incident light is determined depending on an arrangement direction of the liquid crystal molecules. Accordingly, a desired image can be displayed by adjusting the potential difference between the two electrodes.

An OLED display includes a hole injection electrode (anode), an electron injection electrode (cathode), and an organic emission layer that is formed therebetween. The OLED display is a self-emission display that emits light through recombination of holes that are injected from the anode and electrons that are injected from the cathode in the organic emission layer.

However, because such a display device uses a heavy and fragile glass substrate, it may not be suitable for portable and large scale displays. Accordingly, a display device using a flexible substrate such as a plastic substrate having light weight, impact resistance, and flexibility has been developed. However, the plastic substrate is easily expanded by high temperatures during the manufacturing process due to a weak heat property. Accordingly, misalignment between thin film patterns may occur due to the expansion of the substrate.

### SUMMARY OF THE INVENTION

A flexible display panel according to an embodiment of the present invention includes a flexible substrate, a gate line formed on the substrate and including a gate electrode, a gate insulating layer formed on the substrate, a semiconductor layer formed on the gate insulating layer and disposed substantially on the entire gate electrode, a source electrode and a drain electrode formed on the semiconductor layer, and a pixel electrode connected to the drain electrode.

The semiconductor layer may have the same planar shape as the gate electrode at least in part.

The semiconductor layer may have a boundary substantially coinciding with a boundary of the gate electrode.

The substrate may include a plastic.

The display panel may further include a barrier layer disposed on at least one surface of the substrate.

A method of manufacturing a flexible display panel according to an embodiment of the present invention includes forming a gate line including a gate electrode on a flexible substrate, depositing a gate insulating layer, depositing a semiconductor layer on the gate insulating layer, patterning the semiconductor layer to form a first semiconductor member, wherein a size of the first semiconductor member is sufficient to cover the gate electrode shifted by a deformation of the substrate during the method of manufacturing the flexible display panel, patterning the first semiconductor member to form a second semiconductor member, forming a data line including a source electrode and a drain electrode on the second semiconductor member and the gate insulating layer, and forming a pixel electrode connected to the drain electrode.

The first semiconductor member substantially fully covers the gate electrode.

The size of the first semiconductor member may be determined such that the first semiconductor member covers positions of the gate electrode before and after the formation of the first semiconductor member.

The patterning of the first semiconductor member may remove a portion of the first semiconductor member corresponding to the position of the gate electrode before the formation of the first semiconductor member.

The size of the first semiconductor member may be determined such that the first semiconductor member covers positions of the gate electrode before and after the deposition of the gate insulating layer and the semiconductor layer.

The patterning of the first semiconductor member may remove a portion of the first semiconductor member corresponding to the position of the gate electrode after the deposition of the gate insulating layer and the semiconductor layer.

The patterning of the semiconductor layer to form a second semiconductor member may be performed by self alignment using the gate electrode as a light blocking mask.

The patterning of the semiconductor layer to form a second semiconductor member may include backward exposing the substrate using the gate electrode as a light blocking mask.

The patterning of the semiconductor layer to form a second semiconductor member may include coating a photoresist film on a first semiconductor member, backward exposing the photoresist film using the gate electrode as a light blocking mask at the back of the substrate, developing the exposed photoresist film to form a photoresist pattern having the same planar size as the gate electrode, and etching the semiconductor layer using the photoresist pattern as an etching mask.

The coating of the photoresist film may be performed by laminating a photoresist having a film form.

The substrate may include a plastic.

### BRIEF DESCRIPTION OF THE DRAWINGS

FIG. 1 is a layout view of a TFT array panel according to an embodiment of the present invention.

FIG. 2 is a sectional view of the TFT array panel shown in FIG. 1 taken along the line II-II

FIG. 3 is a sectional view of the TFT array panel shown in FIG. 1 taken along the line III-III

FIG. 4 is a layout view of the TFT array panel during a manufacturing method thereof according to an embodiment of the present invention.

FIG. 5 and FIG. 6 are sectional views of the TFT array panel shown in FIG. 4 taken along the lines V-V and VI-VI, respectively.

FIG. 7 is a layout view of the TFT array panel during a manufacturing method thereof according to an embodiment of the present invention.

FIG. 8 and FIG. 9 are sectional views of the TFT array panel shown in FIG. 7 taken along the lines VIII-VIII and IX-IX, respectively.

FIG. 10A to FIG. 10C are sectional views for showing a manufacturing method of the TFT array panel shown in FIG. 7 to FIG. 9.

FIG. 11A to FIG. 11E are sectional views for showing a manufacturing method of the TFT array panel shown in FIG. 7 to FIG. 9.

FIG. 12 is a layout view of the TFT array panel during a manufacturing method thereof according to an embodiment of the present invention.

FIG. 13 and FIG. 14 are sectional views of the TFT array panel shown in FIG. 12 taken along the lines XIII-XIII and XIV-XIV, respectively.

FIG. 15 is a layout view of the TFT array panel during a manufacturing method thereof according to an embodiment of the present invention.

FIG. 16 and FIG. 17 are sectional views of the TFT array panel shown in FIG. 15 taken along the lines XVI-XVI and XVII-XVII, respectively.

Reference Numerals Indicating Elements in the Drawings
40 . . . photosensitive film
42 . . . photosensitive film pattern
81, 82 . . . contact assistants
83 . . . overpass
110 . . . substrate
110a . . . barrier layer
131 . . . storage electrode line
133a, 133b . . . storage electrode
121, 129 . . . gate line
124 . . . gate electrode
140 . . . gate insulating layer
150, 151, 152, 154 . . . semiconductor
160, 162, 163, 164, 165 . . . ohmic contact layer
171, 179 . . . data line
173 . . . source electrode
175 . . . drain electrode
180 . . . passivation layer
181, 182, 183a, 183b, 185 . . . contact hole
191 . . . pixel electrode

### DETAILED DESCRIPTION OF EXEMPLARY EMBODIMENTS

Exemplary embodiments of the present invention will be described more fully hereinafter with reference to the accompanying drawings. This invention may, however, be embodied in many different forms and should not be construed as limited to the embodiments set forth herein.

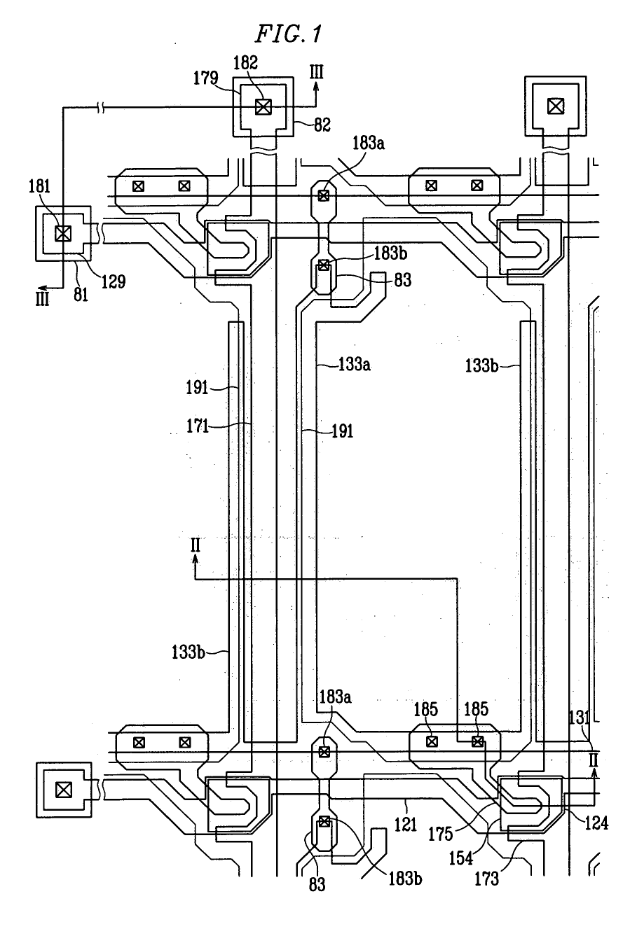

In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or intervening elements may also be present. A thin film transistor (TFT) array panel according to an embodiment of the present invention will be described in detail with reference to FIG. 1 to FIG. 3.

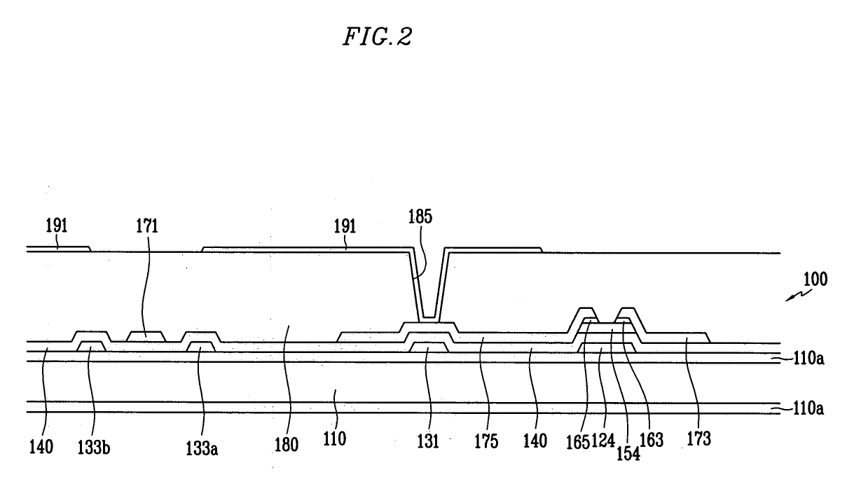

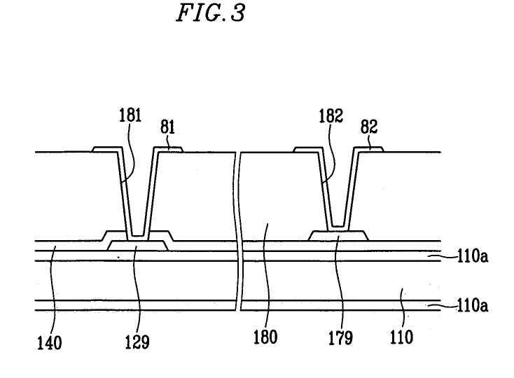

FIG. 1 is a layout view of a TFT array panel according to an embodiment of the present invention, FIG. 2 is a sectional view of the TFT array panel shown in FIG. 1 taken along the line II-II, and FIG. 3 is a sectional view of the TFT array panel shown in FIG. 1 taken along the line III-III.

A plurality of gate lines 121 and a plurality of storage electrode lines 131 are formed on a flexible insulating substrate 110 such as, for example, transparent plastic.

Barrier layers 110a are disposed on two surfaces, for example, as shown in FIGS. 2 and 3, top and bottom surfaces of the substrate 110, respectively. The barrier layers 110a prevent oxygen or moisture from penetrating the substrate 110. The barrier layers 110a may comprise, for example, silicon oxide (SiOx) or silicon nitride (SiNx). At least one of the barrier layers 110a may be omitted.

The gate lines 121 transmit gate signals and extend substantially in a transverse direction. Referring to FIG. 1, each of the gate lines 121 includes a plurality of gate electrodes 124 projecting downward and an end portion 129 having a large area for contact with another layer or an external driving circuit. A gate driving circuit (not shown) for generating the gate signals may be mounted on a flexible printed circuit (FPC) film (not shown), which may be attached to the substrate 110, directly mounted on the substrate 110, or integrated with the substrate 110. The gate lines 121 may extend to be connected to a driving circuit that may be integrated with the substrate 110.

The storage electrode lines 131 are supplied with a predetermined voltage, and each of the storage electrode lines 131 includes a portion extending substantially parallel to the gate lines 121 and a plurality of pairs of first and second storage electrodes 133a and 133b branching from the extending portion. Each of the storage electrode lines 131 is disposed between two adjacent gate lines 121, and the extending portion is closer to one of the two adjacent gate lines 121. Each of the storage electrodes 133a and 133b has a fixed end portion connected to the extending portion and a free end portion disposed opposite thereto. The fixed end portion of the first storage electrode 133a has a large area and the free end portion thereof is bifurcated into a linear branch and a curved branch. The storage electrode lines 131 are not limited to the above-described configuration, and may have various shapes and arrangements.

The gate lines 121 and the storage electrode lines 131 may comprise, for example, an Al-containing metal such as Al and an Al alloy, a Ag-containing metal such as Ag and a Ag alloy, a Cu-containing metal such as Cu and a Cu alloy, a Mo-containing metal such as Mo and a Mo alloy, Cr, Ta, or Ti. The gate and storage electrode lines 121, 131 may have a multi-layered structure including two conductive films (not shown) having different physical characteristics. One of the two films may comprise a low resistivity metal including, for example, an Al-containing metal, a Ag-containing metal, and a Cu-containing metal for reducing signal delay or voltage drop. The other film may comprise a material, such as a Mo-containing metal, Cr, Ta, or Ti, which has good physical, chemical, and electrical contact characteristics with other materials such as indium tin oxide (ITO) or indium zinc oxide (IZO). Examples of the combination of the two films are a lower Cr film and an upper Al (alloy) film, and a lower Al (alloy) film and an upper Mo (alloy) film. However, it is to be understood that the gate lines 121 and the storage electrode lines 131 may comprise various metals or conductors.

The lateral sides of the gate lines 121 and the storage electrode lines 131 are inclined relative to a surface of the substrate 110, and the inclination angle thereof ranges from about 30 degrees to about 80 degrees.

A gate insulating layer 140 that may comprise, for example, silicon nitride (SiNx) or silicon oxide (SiOx) is formed on the gate lines 121 and the storage electrode lines 131.

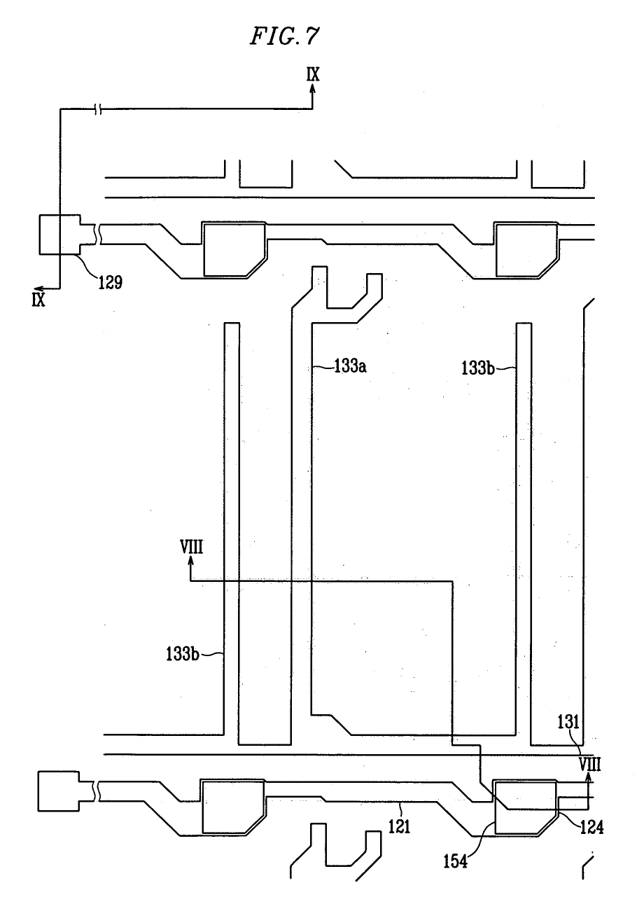

A plurality of semiconductor islands 154, which may comprise, for example, hydrogenated amorphous silicon (abbreviated to “a-Si”) or polysilicon, are formed on the gate insulating layer 140. The semiconductor islands 154 are disposed on the gate electrodes 124. Referring to FIG. 1, the semiconductor islands 154 are disposed to span substantially the entire width of the gate lines 121. For example, as shown in FIG. 1 (and FIG. 7), the semiconductor islands 154 may have substantially the same planar shape as the gate electrodes 124 at least in part. In other words, some boundaries of the semiconductor islands 154 may coincide with boundaries of the gate electrodes 124.

A plurality of pairs of ohmic contact islands 163 and 165 are formed on the semiconductor islands 154. The ohmic contacts 163 and 165 may comprise, for example, silicide or n+hydrogenated a-Si heavily doped with n type impurity such as phosphorous.

The lateral sides of the semiconductor islands 154 and the ohmic contacts 163 and 165 are inclined relative to the surface of the substrate 110, and the inclination angles thereof may be in a range of about 30 degrees to about 80 degrees.

A plurality of data lines 171 and a plurality of drain electrodes 175 are formed on the ohmic contacts 163 and 165 and the gate insulating layer 140.

The data lines 171 transmit data signals and extend substantially in the longitudinal direction to intersect the gate lines 121. Each of the data lines 171 also intersects the storage electrode lines 131 and runs between adjacent pairs of storage electrodes 133a and 133b. Each data line 171 includes a plurality of source electrodes 173 projecting toward the gate electrodes 124 and curved in a J-shape. Each data line 171 includes an end portion 179 having a large area for contact with another layer or an external driving circuit. A data driving circuit (not shown) for generating the data signals may be mounted on an FPC film (not shown), which may be attached to the substrate 110, directly mounted on the substrate 110, or integrated with the substrate 110. The data lines 171 may extend to be connected to a data driving circuit that may be integrated with the substrate 110.

The drain electrodes 175 are separated from the data lines 171, and are disposed opposite the source electrodes 173 with respect to the gate electrodes 124. Each of the drain electrodes 175 includes a first end portion, which is wider than a second end portion. The wider first end portion overlaps a storage electrode line 131 and the narrower second end portion is partly enclosed by a source electrode 173.

A gate electrode 124, a source electrode 173, and a drain electrode 175 along with a semiconductor island 154 form a TFT having a channel formed in the semiconductor island 154 between the source electrode 173 and the drain electrode 175.

The data lines 171 and the drain electrodes 175 may comprise a refractory metal such as Mo, Cr, Ta, Ti, or alloys thereof. The data lines 171 may have a multi-layered structure including a refractory metal film (not shown) and a low resistivity film (not shown). Examples of the multi-layered structure are a double-layered structure including a lower Cr/Mo (alloy) film and an upper Al (alloy) film, and a triple-layered structure of a lower Mo (alloy) film, an intermediate Al (alloy) film, and an upper Mo (alloy) film. However, it is to be understood that the data lines 171 and the drain electrodes 175 may comprise various metals or conductors.

The data lines 171 and the drain electrodes 175 have inclined edge profiles, and the inclination angles thereof range from about 30 degrees to about 80 degrees.

The ohmic contacts 161 and 165 are interposed between the underlying semiconductor islands 154 and the overlying conductors 171 and 175 thereon, and reduce the contact resistance therebetween. The semiconductor islands 154 include some exposed portions, which are not covered with the data lines 171 and the drain electrodes 175, such as portions located between the source electrodes 173 and the drain electrodes 175.

A passivation layer 180 is formed on the data lines 171, the drain electrodes 175, and the exposed portions of the semiconductor islands 154. The passivation layer 180 may comprise an inorganic or organic insulator and may have a flat top surface. Examples of the inorganic insulator include silicon nitride and silicon oxide. The organic insulator may have photosensitivity and a dielectric constant less than about 4.0. The passivation layer 180 may include a lower film of an inorganic insulator and an upper film of an organic insulator such that it has the insulating characteristics of the organic insulator while preventing the exposed portions of the semiconductor islands 154 from being damaged by the organic insulator.

The passivation layer 180 has a plurality of contact holes 182 and 185 exposing the end portions 179 of the data lines 171 and the drain electrodes 175, respectively. The passivation layer 180 and the gate insulating layer 140 have a plurality of contact holes 181 exposing the end portions 129 of the gate lines 121, a plurality of contact holes 183a exposing portions of the storage electrode lines 131 near the fixed end portions of the first storage electrodes 133a, and a plurality of contact holes 183b exposing the branches, for example, linear branches, of the free end portions of the first storage electrodes 133a.

A plurality of pixel electrodes 191, a plurality of overpasses 83, and a plurality of contact assistants 81 and 82 are formed on the passivation layer 180. The pixel electrodes 191, overpasses 83 and contact assistants 81 and 82 may comprise a transparent conductor such as ITO or IZO or a reflective conductor such as Ag, Al, Cr or alloys thereof.

The pixel electrodes 191 are physically and electrically connected to the drain electrodes 175 through the contact holes 185 such that the pixel electrodes 191 receive data voltages from the drain electrodes 175. The pixel electrodes 191 supplied with the data voltages generate electric fields in cooperation with a common electrode (not shown) of an opposing display panel (not shown) supplied with a common voltage, which determine the orientation of liquid crystal molecules (not shown) of a liquid crystal layer (not shown) disposed between the two electrodes to determine the polarization of light passing through the liquid crystal layer. A pixel electrode 191 and the common electrode form a capacitor referred to as a “liquid crystal capacitor” that stores applied voltages after the TFT turns off.

A pixel electrode 191 and a drain electrode 175 connected thereto overlap a storage electrode line 131 including storage electrodes 133a and 133b.The pixel electrode 191, the drain electrode 175 connected thereto, and the storage electrode line 131 form an additional capacitor referred to as a “storage capacitor” that enhances the voltage storing capacity of the liquid crystal capacitor.

The contact assistants 81 and 82 are connected to the end portions 129 of the gate lines 121 and the end portions 179 of the data lines 171 through the contact holes 181 and 182, respectively. The contact assistants 81 and 82 protect the end portions 129 and 179 and enhance the adhesion between the end portions 129 and 179 and external devices.

The overpasses 83 cross over the gate lines 121 and are connected to exposed portions of the storage electrode lines 131 and exposed linear branches of the free end portions of the first storage electrodes 133a through the contact holes 183a and 183b, respectively, which are disposed opposite each other with respect to the gate lines 121. The storage electrode lines 131 including the storage electrodes 133a and 133b along with the overpasses 83 can be used for repairing defects in the gate lines 121, the data lines 171, or the TFTs.

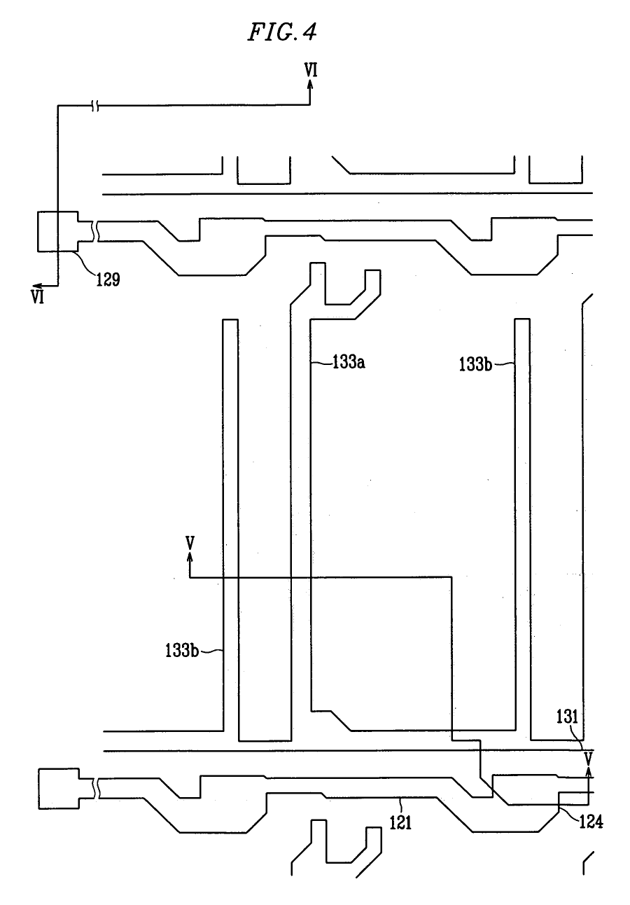

A method of manufacturing the TFT array panel shown in FIG. 1 to FIG. 3 according to an embodiment of the present invention will be described with reference to FIG. 4 to FIG. 17 along with FIG. 1 to FIG. 3.

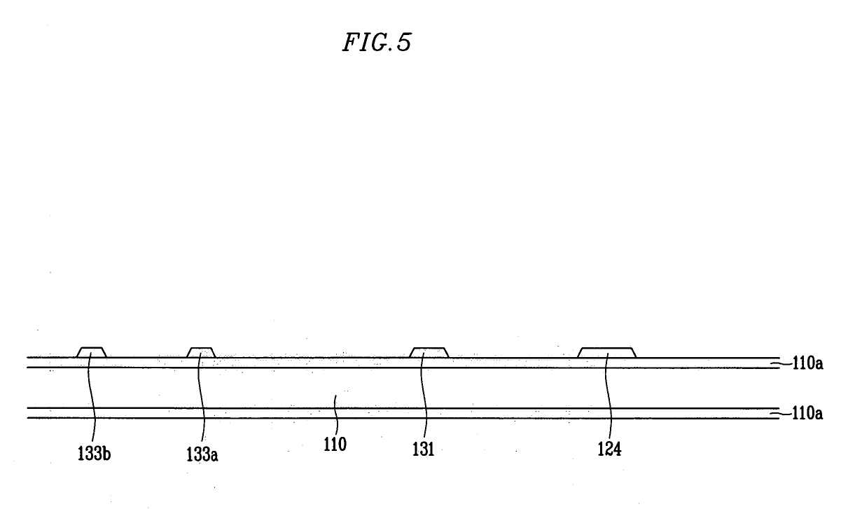

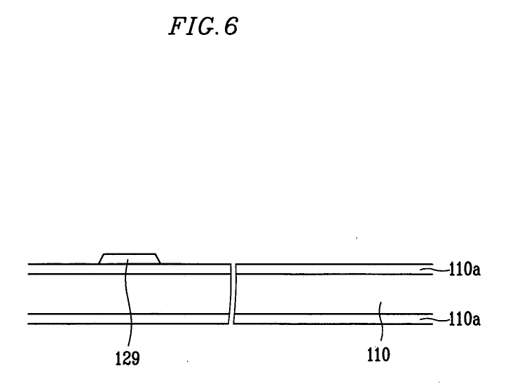

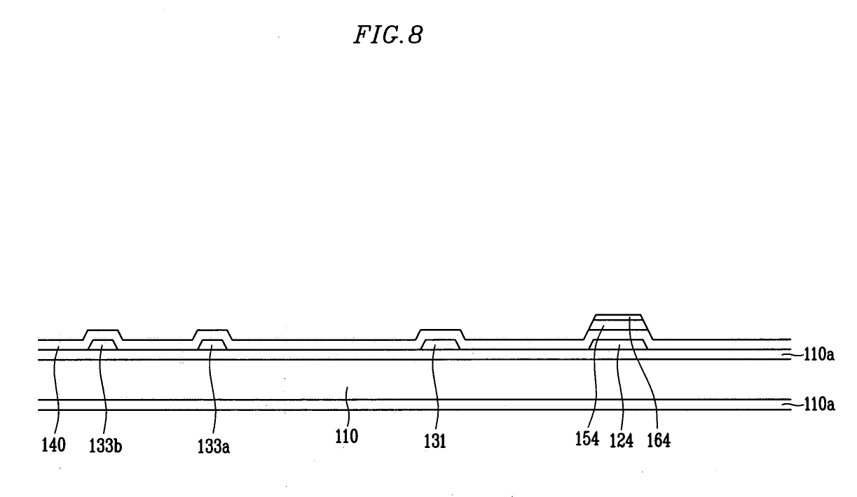

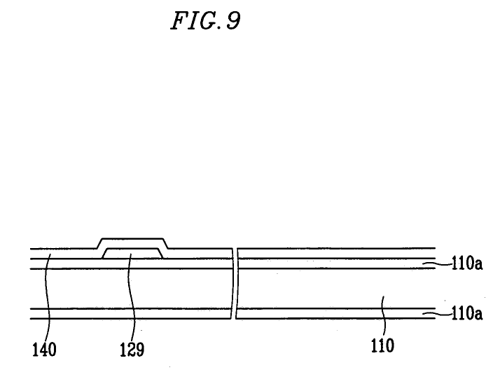

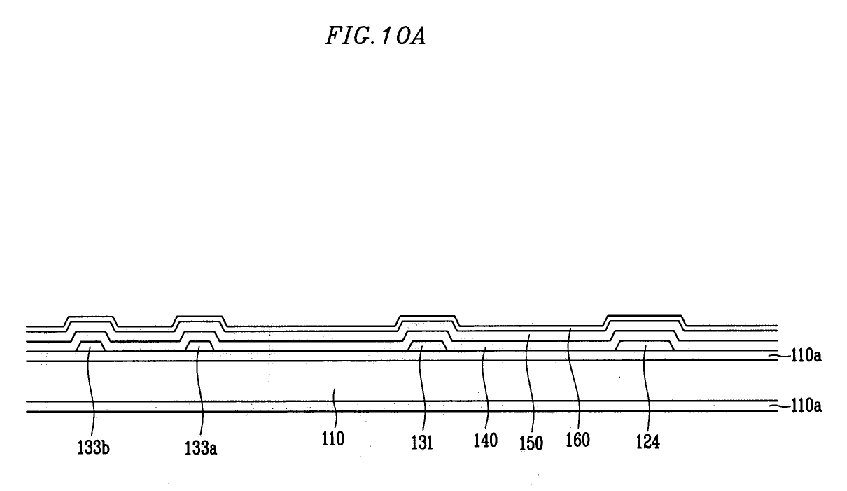

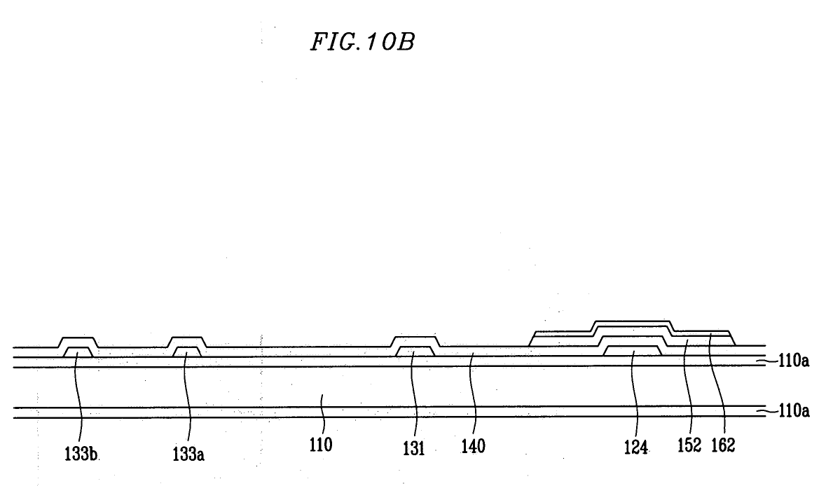

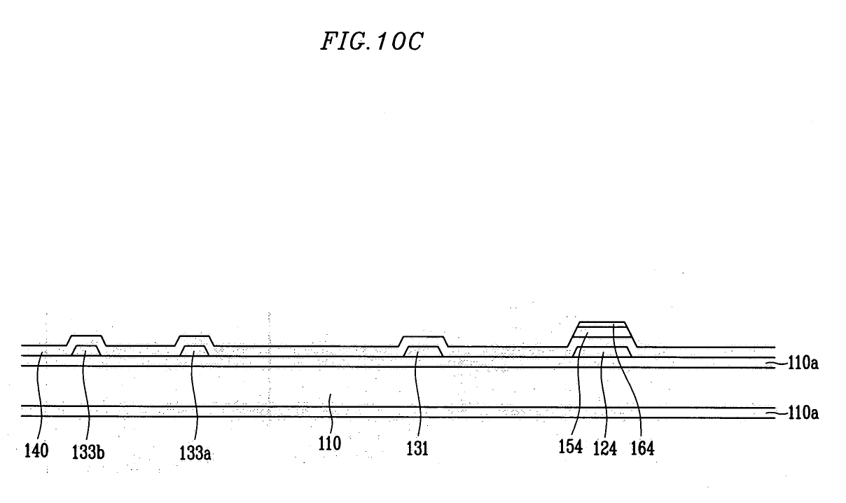

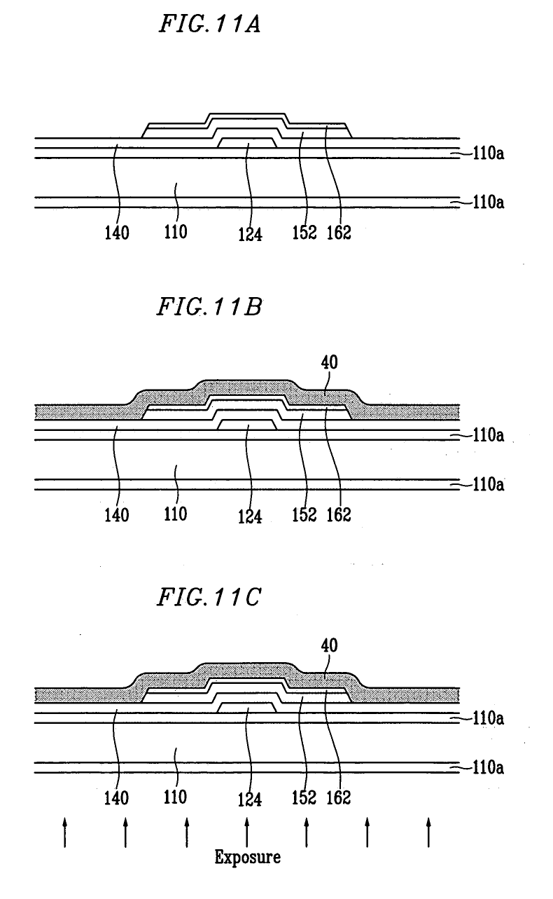

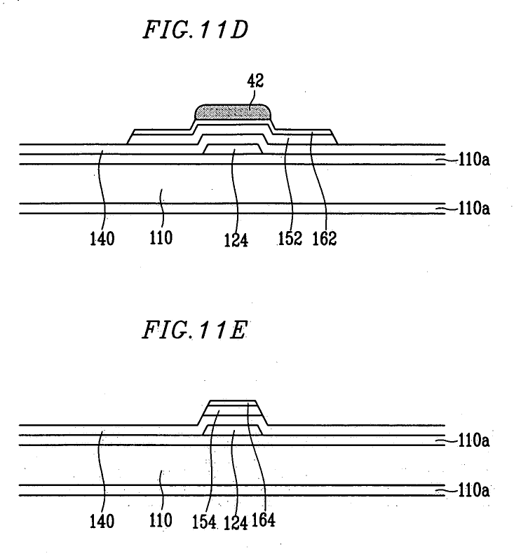

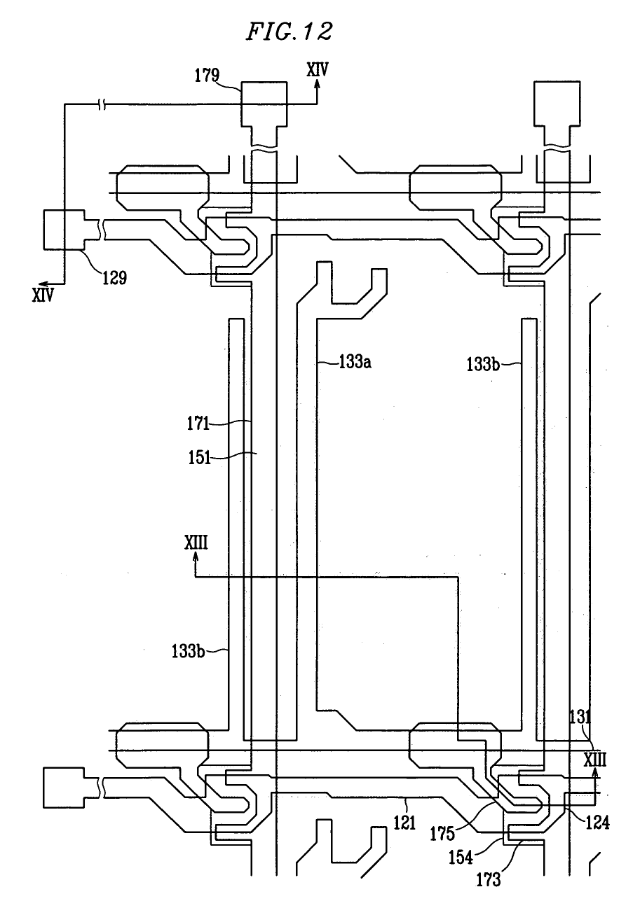

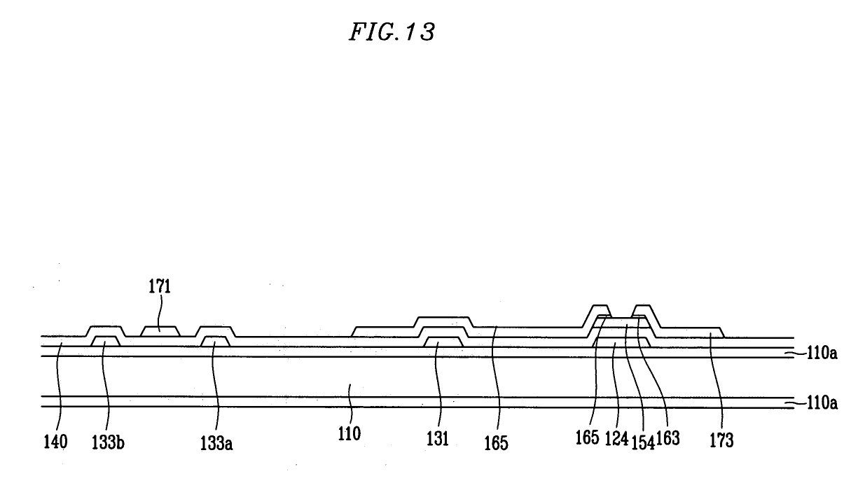

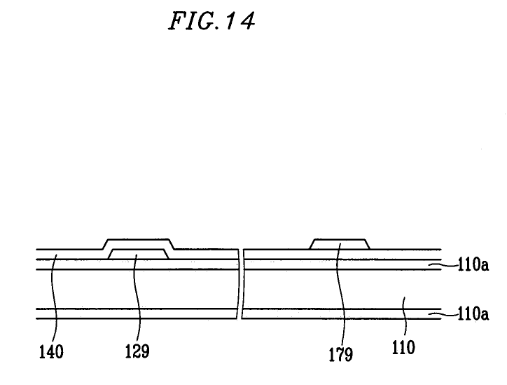

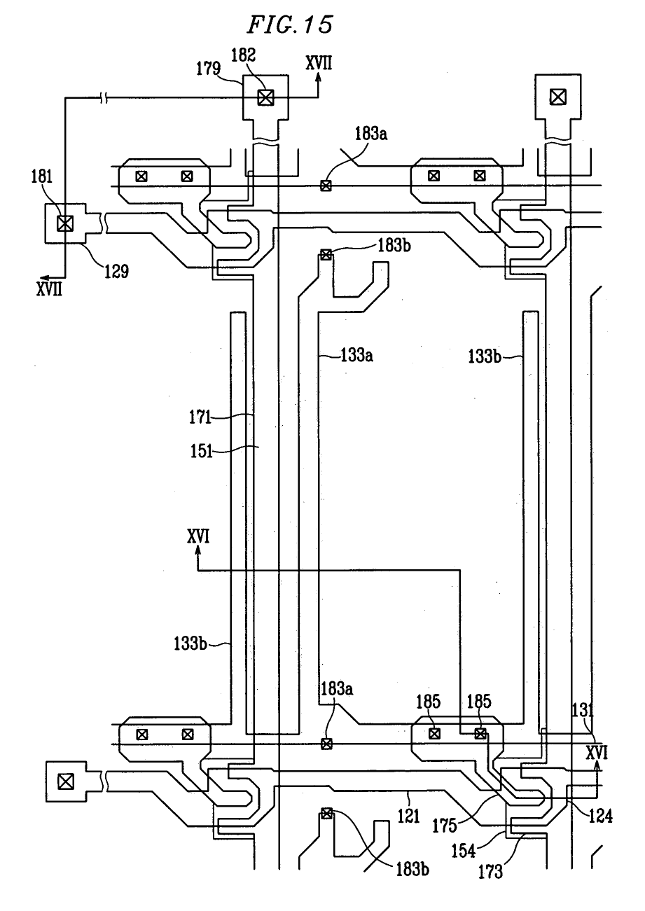

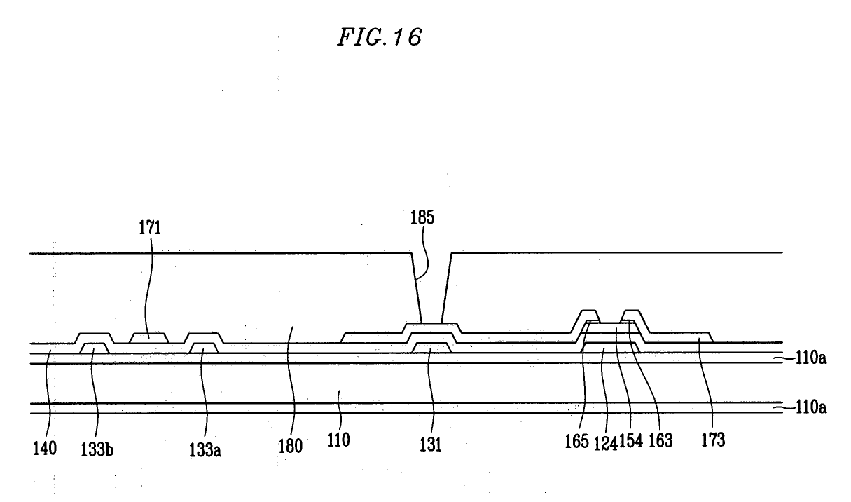

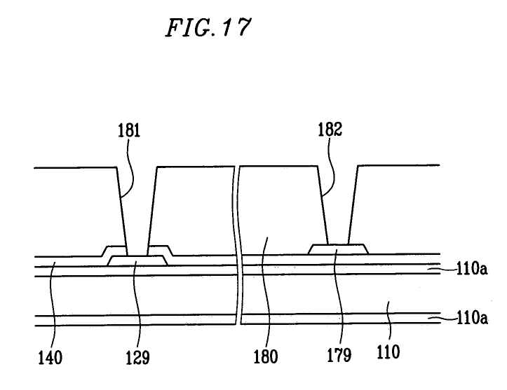

FIG. 4, FIG. 7, FIG. 12, and FIG. 15 are layout views of the TFT array panel during a manufacturing method thereof according to an embodiment of the present invention. FIG. 5 and FIG. 6 are sectional views of the TFT array panel shown in FIG. 4 respectively taken along the lines V-V and VI-VI. FIG. 8 and FIG. 9 are sectional views of the TFT array panel shown in FIG. 7 respectively taken along the lines VIII-VIII and IX-IX. FIG. 10A to FIG. 10C are sectional views of the TFT array panel shown in FIG. 7 taken along line VIII-VIII in step(s) following the step(s) shown in FIGS. 8 and 9. FIG. 11A to FIG. 11E are sectional views of a portion of the TFT array panel shown in FIG. 7 taken along a portion of a line IX-IX in step(s) following the step(s) shown in FIGS. 10A to 10C. FIG. 13 and FIG. 14 are sectional views of the TFT array panel shown in FIG. 12 respectively taken along the lines XIII-XIII and XIV-XIV, and FIG. 16 and FIG. 17 are sectional views of the TFT array panel shown in FIG. 15 respectively taken along the lines XVI-XVI and XVII-XVII.

Referring to FIG. 4 to FIG. 6, a metal film is deposited on a flexible substrate 110 covered with protection films 110a by, for example, a sputtering process. Then the metal film is patterned by photolithography and etching to form a plurality of gate lines 121 including gate electrodes 124 and end portions 129 and a plurality of storage electrode lines 131 including storage electrodes 133a and 133b. The flexible substrate 110 may be fixed on a supporter (not shown) such as a glass substrate before the deposition of the metal film, and then subsequent processes may be performed thereon.

Next, a gate insulating layer 140 is deposited on the substrate 110, and then a plurality of intrinsic semiconductor islands 154 and a plurality of extrinsic semiconductor islands 164 are formed on the gate electrodes 124 as shown in FIG. 7 to FIG. 9.

The formation of the gate insulating layer 140, the intrinsic semiconductor islands 154, and the extrinsic semiconductor islands 164 will be described in more detail with reference to FIG. 10A to FIG. 10C.

Referring to FIG. 10A, the gate insulating layer 140, an intrinsic a-Si layer 150, and an extrinsic a-Si layer 160 are sequentially deposited by, for example, plasma enhanced chemical vapor deposition (PECVD). The flexible substrate 110 made of plastic, for example, may expand by heat generated during the deposition of the layers 140, 150 and 160, and thereby the gate lines 121 including the gate electrodes 124, and the storage electrode lines 131 may be shifted from their initial positions.

The intrinsic a-Si layer 150 and the extrinsic a-Si layer 160 are patterned by photolithography and etching to form a plurality of preliminary intrinsic semiconductor islands 152 and a plurality of preliminary extrinsic semiconductor islands 162. The preliminary intrinsic semiconductor islands 152 and the preliminary extrinsic semiconductor islands 162 have sufficient areas to entirely cover the initial positions and the shifted positions of the gate electrodes 124 as shown in FIG. 10B.

The preliminary intrinsic semiconductor islands 152 and the preliminary extrinsic semiconductor islands 162 may lessen the stress applied to the substrate 110 to fix the substrate 110 such that the substrate 110 may be restored to its original size at room temperature.

When the substrate 110 restores its initial size, the gate electrodes 124 may be also restored to their original positions.

The first intrinsic semiconductor islands 152 and the first extrinsic semiconductor islands 162 are successively patterned by photolithography and etching based on the restored disposition of the gate electrodes 124 to form the intrinsic semiconductor islands 154 and the extrinsic semiconductor islands 164.

Then, the intrinsic semiconductor islands 154 and the extrinsic semiconductor islands 164 can be placed at their accurate positions. The misalignment between the gate electrodes 124 and the second semiconductor islands 154 and 164 may therefore be reduced.

An example of patterning the first semiconductor islands 152 and 162 to form the second semiconductor islands 154 and 164 will be described in more detail with reference to FIG. 11A to FIG. 11E.

After the preliminary intrinsic semiconductor islands 152 and the preliminary extrinsic semiconductor islands 162 are formed as shown in FIG. 11A, a photoresist film 40 is deposited on the whole surface the substrate 110 as shown in FIG. 11B.

The photoresist film 40 may be formed by laminating a previously produced photoresist film form or by coating a liquid photosensitive material.

Next, the photoresist film 40 is exposed to light from the rear surface of the substrate 110 using the gate electrodes 124 as a light blocking mask as shown in FIG. 11C, and then the exposed photoresist film 40 is developed to form a photoresist 42 having substantially the same planar shape as the gate lines 121 including the gate electrodes 124 as shown in FIG. 11D.

Referring to FIG. 11E, the preliminary intrinsic semiconductor islands 152 and the preliminary extrinsic semiconductor islands 162 are etched using the photoresist 42 as an etching mask to form the intrinsic semiconductor islands 154 and the extrinsic semiconductor islands 164, and the photoresist 42 is removed.

The above-described rear exposure for the intrinsic semiconductor islands 154 and the extrinsic semiconductor islands 164, performed in a self-aligned manner, can place the intrinsic semiconductor islands 154 as channel portions of thin film transistors at accurate positions. In addition, the rear exposure requires no additional photomask.

Referring to FIG. 12 to FIG. 14, a metal film is deposited and patterned by photolithography and etching to form a plurality of data lines 171, including source electrodes 173 and end portions 179, and a plurality of drain electrodes 175.

Thereafter, exposed portions of the extrinsic semiconductor islands 164, which are not covered with the data lines 171 and the drain electrodes 175, are removed to complete a plurality of ohmic contact islands 163 and 165 and to expose portions of the intrinsic semiconductor islands 154.

As shown in FIG. 15 to FIG. 17, a passivation layer 180 is deposited, and the passivation layer 180 and the gate insulating layer 140 are patterned to form a plurality of contact holes 181, 182, 183a, 183b, and 185.

As shown in FIG. 1 to FIG. 3, a transparent conducting material, such as ITO or IZO, is deposited on the passivation layer 180 by, for example, sputtering, and is patterned to form a plurality of pixel electrodes 191, a plurality of contact assistants 81 and 82, and a plurality of overpasses 83.

While this invention has been described in connection with exemplary embodiments, it is to be understood that the invention is not limited to the disclosed embodiments, but is intended to cover various modifications and equivalent arrangements included within the spirit and scope of the appended claims.

What is claimed is:

1. A flexible display panel, comprising:
a flexible substrate;
a gate line formed on the substrate, the gate line including a gate electrode;
a gate insulating layer formed on the substrate;
a semiconductor layer formed on the gate insulating layer and disposed substantially on the entire gate electrode;
a source electrode and a drain electrode formed on the semiconductor layer; and
a pixel electrode connected to the drain electrode.

2. The flexible display panel of claim 1, wherein the semiconductor layer has the same planar shape as the gate electrode at least in part.

3. The flexible display panel of claim 1, wherein the semiconductor layer has a boundary substantially coinciding with a boundary of the gate electrode.

4. The flexible display panel of claim 1, wherein the substrate comprises a plastic.

5. The flexible display panel of claim 1, further comprising a barrier layer disposed on at least one surface of the substrate.

6. A method of manufacturing a flexible display panel, comprising:
forming a gate line including a gate electrode on a flexible substrate;
depositing a gate insulating layer on the substrate;
depositing a semiconductor layer on the gate insulating layer;
patterning the semiconductor layer to form a first semiconductor member, wherein a size of the first semiconductor member is sufficient to cover the gate electrode shifted by deformation of the substrate during the method of manufacturing the flexible display panel;
patterning the first semiconductor member to form a second semiconductor member;
forming a data line including a source electrode and a drain electrode on the second semiconductor member and the gate insulating layer; and
forming a pixel electrode connected to the drain electrode.

7. The method of claim 6, wherein the first semiconductor member substantially covers the entire gate electrode.

8. The method of claim 6, wherein the size of the first semiconductor member is determined such that the first semiconductor member covers positions of the gate electrode before and after the formation of the first semiconductor member.

9. The method of claim 8, wherein the patterning of the first semiconductor member removes a portion of the first semiconductor member corresponding to a position of the gate electrode before the formation of the first semiconductor member.

10. The method of claim 6, wherein the size of the first semiconductor member is determined such that the first semiconductor member covers positions of the gate electrode before and after the deposition of the gate insulating layer and the semiconductor layer.

11. The method of claim 10, wherein the patterning of the first semiconductor member removes a portion of the first semiconductor member corresponding to a position of the gate electrode after the deposition of the gate insulating layer and the semiconductor layer.

12. The method of claim 6, wherein the patterning of the first semiconductor member comprises self alignment light exposure using the gate electrode as a light blocking mask.

13. The method of claim 12, wherein the patterning of the first semiconductor member comprises exposing the substrate to light from a rear surface of the substrate.

14. The method of claim 6, wherein the patterning of the first semiconductor member comprises:
depositing a photoresist film on the first semiconductor member;
exposing the photoresist film to light from a rear surface of the substrate;
developing the photoresist film to form a photoresist after the light exposure; and
etching the semiconductor layer using the photoresist as an etching mask.

15. The method of claim 14, wherein the deposition of the photoresist film comprises:
laminating a pre-formed photoresist film on the substrate.

16. The method of claim 6, wherein the substrate comprises a plastic.
